(19) United States
(12) Patent Application Publication
(10) Pub. No.: US 2009/0116949 A1
(43) Pub. Date: May 7, 2009

(54) Wafer Bonding Apparatus and Method

(76) Inventor: Chang Hun Han, Icheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/250,013

(22) Filed: Oct. 13, 2008

(30) Foreign Application Priority Data
Nov. 5, 2007 (KR) 10-2007-0112163

(51) Int. Cl. H01L 21/68

(52) U.S. Cl. 414/757; 414/816

(57) ABSTRACT

A wafer bonding apparatus and method are provided. The wafer bonding apparatus can include an aligning unit, and the aligning unit can include a rotating roller for rotating at least two wafers, an aligning bar for aligning the at least two wafers, and a notch alignment sensor for sensing at least two notches of each of the at least two wafers.

### CROSS-REFERENCE TO RELATED APPLICATION

The present application claims the benefit under 35 U.S.C. §119 of Korean Patent Application No. 10-2007-0112163, filed Nov. 5, 2007, which is hereby incorporated by reference in its entirety.

### BACKGROUND

During preparation of semiconductor chips for various applications, a bonding process is sometimes performed on two or more wafers. In such a wafer bonding process, alignment accuracy is critical.

In many related art wafer bonding processes, notches are generally formed one at a time, leading to low alignment accuracy for the wafer bonding.

Thus, there exists a need in the art for an improved wafer bonding apparatus and process.

### BRIEF SUMMARY

Embodiments of the present invention provide a wafer bonding apparatus and method that can improve the alignment accuracy between two or more wafers.

In one embodiment, a wafer bonding apparatus can comprise: an aligning unit which can comprise: a rotating roller for rotating at least two wafers; an aligning bar for aligning the at least two wafers; and a notch alignment sensor for sensing at least two notches of each wafer of the at least two wafers.

In another embodiment, a wafer bonding method can comprise: sensing at least two notches of each wafer of at least two wafers; aligning the at least two wafers; and bonding the at least two wafers.

The details of one or more embodiments are set forth in the accompanying drawings and the description below. Other features will be apparent to one skilled in the art from the detailed description, the drawings, and the claims.

### BRIEF DESCRIPTION OF THE DRAWINGS

FIG. 1A and FIG. 1B are a schematic view showing an aligning unit of a wafer bonding apparatus according to an embodiment of the present invention.

FIGS. 2 to 4 are schematic views showing notches in a wafer bonding method according to an embodiment of the present invention.

### DETAILED DESCRIPTION

A wafer bonding apparatus and method according to embodiments of the present invention will now be described in detail with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

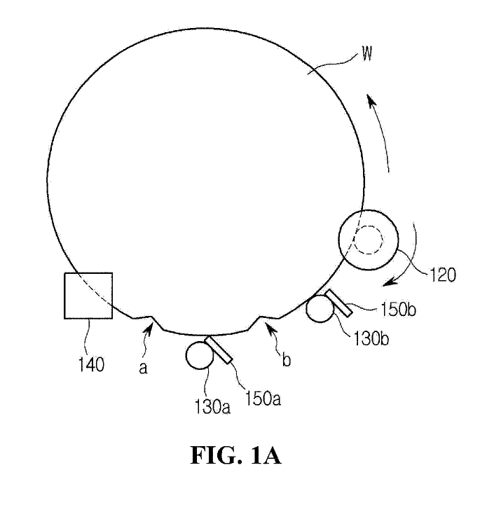

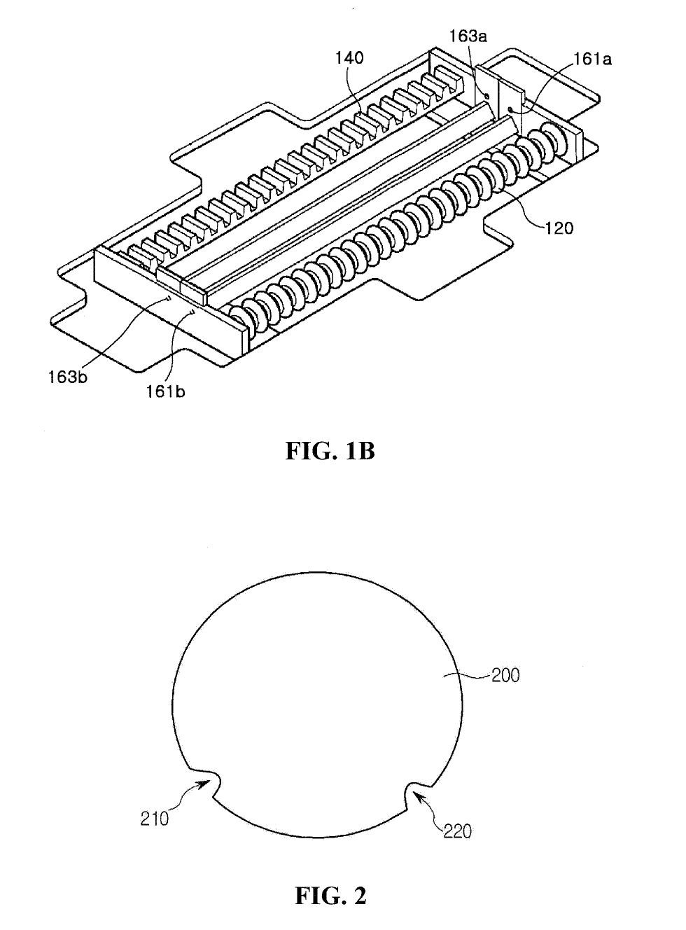

FIG. 1A and FIG. 1B are a schematic view showing an aligning unit of a wafer bonding apparatus according to an embodiment of the present invention.

Referring to FIG. 1A and FIG. 1B, in an embodiment, a wafer bonding apparatus can comprise an aligning unit, and the aligning unit can include a rotating roller 120 for rotating a wafer W. The aligning unit can also include aligning bars 130a and 130b for aligning the wafer W and a notch alignment sensor (161a, 161b, 163a, 163b) for sensing at least two notches of the wafer W.

In certain embodiments, the aligning unit can be included in a wafer bonding apparatus configured for bonding two wafers, and the notch alignment sensor can sense at least two notches in each wafer to measure the alignment accuracy for wafer bonding.

In one embodiment, the notches of the wafer W can be provided in an equidistant arrangement such that the distance between any two notches is approximately the same. In an alternative embodiment, the notches of the wafer W can be provided in a non-equidistant arrangement such that the distance between any two notches is not necessarily approximately the same.

Additionally, in an embodiment, at least one notch of the wafer W can be provided in an asymmetric structure such that a top surface of the wafer can be distinguished from a bottom surface of the wafer. In a further embodiment, each notch of the wafer W can be provided in such an asymmetric structure.

The wafer bonding apparatus can include a supporting member 140 for supporting the wafer W.

In an embodiment, the wafer bonding apparatus can include elevator plates 150a and 150b, which can elevate the wafer W into close contact with the rotating roller 120 such that the wafer W can be rotated for realignment.

While the figures shows an apparatus with two aligning bars for aligning wafers with two notches, embodiments of the present invention are not limited thereto. An apparatus of the present invention can include additional aligning bars for aligning wafers with additional notches, for example, three notches, four notches, five notches, etc.

In the wafer bonding apparatus according to embodiments of the present invention, alignment can be performed through at least two notches of each of the wafers to be bonded, thereby improving alignment accuracy. Also, a technical limitation that may occur due to mismatching between wafers can be inhibited.

Hereinafter, a wafer bonding method according to embodiments of the present invention will be described.

The wafer W can be rotated by the rotating roller 120, and a first notch ‘a’ can be engaged with a first aligning bar 130a. A second notch ‘b’ can be engaged with a second aligning bar 130b to align the wafer W.

While the figures shows a method for aligning wafers with two notches, embodiments of the present invention are not limited thereto. A method of the present invention can include aligning wafers with additional notches, for example, three notches, four notches, five notches, etc.

When the wafer is again rotated for realignment, the two or more notches of the wafer W can be sensed, and a sensed result can be delivered to a controller.

The present invention can include performing notch sensing to sense two or more notches of each wafer, thereby improving the alignment accuracy for wafer bonding.

In one embodiment, the notches of the wafer W can be formed in an equidistant arrangement such that the distance between any two notches is approximately the same. In an alternative embodiment, the notches of the wafer W can be formed in a non-equidistant arrangement such that the distance between any two notches is not necessarily approximately the same.

Additionally, in an embodiment, at least one notch of the wafer W can be provided in an asymmetric structure such that a top surface of the wafer can be distinguished from a bottom surface of the wafer. In an further embodiment, each notch of the wafer W can be provided in such an asymmetric structure.

The notch alignment sensor can include a light emitting device 161a or 163a and a light receiving device 161b or 163b fixed by a sensor fixing plate installed at both ends of a frame. In an embodiment, the light emitting device (161a, 163a) can emit light of a predetermined wavelength to the notches ‘a’ and ‘b’ of the wafer W aligned by the aligning bars 130a and 130b. The light receiving device (161b or 163b) can receive the light emitting from the light emitting device (161a, 163a), thereby determining whether or not the notches of the wafer W are correctly aligned.

Additionally, the wafer W can be supported by a supporting member 140.

Elevator plates 150a and 150b can elevate the wafer W first aligned by the aligning bars 130a and 130b into close contact with the rotating roller 120 such that the wafer W can be rotated for realignment.

Unlike a typical related art wafer bonding process, in which it is very difficult to achieve precise alignment using a typical wafer, embodiments of the present invention can improve alignment by forming notches in the wafers.

In embodiments of the present invention, two or more notches can be formed in a wafer, and for wafer bonding, an optical signal can be received from a portion where the two or more notches are formed, thereby making it possible to improve alignment of two or more wafers.

FIGS. 2 to 4 show nonlimiting examples of wafers that can be used in the aligning unit and aligning method according to embodiments of the present invention. Referring to FIG. 2, in one embodiment, two notches 210 and 220 can be formed in a wafer 200.

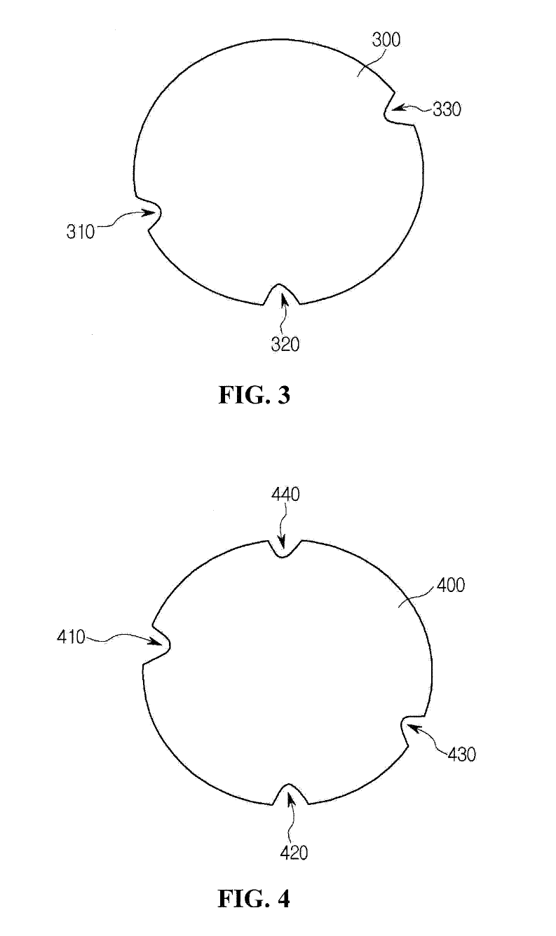

Referring to FIG. 3, in an alternative embodiment, three notches 320, 310, and 330 can be formed in a wafer 300.

Referring to FIG. 4, in yet another alternative embodiment, four notches 410, 420, 430, and 440 can be formed in a wafer 400.

The wafer bonding apparatus and method according to embodiments can enhance the alignment accuracy in bonding two or more wafers.

Also, according to embodiments of the present invention, the technical limitation that may occur due to mismatching between two or more wafers can be inhibited.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A wafer bonding apparatus comprising an aligning unit, the aligning unit comprising:
a rotating roller for rotating at least two wafers;
an aligning bar for aligning the at least two wafers; and
a notch alignment sensor for sensing at least two notches of each wafer of the at least two wafers.

2. The wafer bonding apparatus of claim 1, wherein the apparatus is configured for bonding two wafers.

3. The wafer bonding apparatus of claim 2, wherein the notch alignment sensor senses the at least two notches of each wafer of the two wafers to measure an alignment accuracy for wafer bonding.

4. The wafer bonding apparatus of claim 1, wherein the at least two notches of each wafer are provided in an equidistant arrangement.

5. The wafer bonding apparatus of claim 1, wherein the at least two notches of each wafer are provided in a non-equidistant arrangement.

6. The wafer bonding apparatus of claim 1, wherein at least one of the at least two notches of each wafer is provided in an asymmetric structure.

7. The wafer bonding apparatus of claim 1, wherein each of the at least two notches of each wafer is provided in an asymmetric structure.

8. The wafer bonding apparatus of claim 1, further comprising a supporting member for supporting at least one wafer of the at least two wafers.

9. The wafer bonding apparatus of claim 1, further comprising at least one elevator plate for elevating at least one wafer of the at least two wafers into close contact with the rotating roller.

10. The wafer bonding apparatus of claim 1, wherein each wafer of the at least two wafers has exactly two notches.

11. The wafer bonding apparatus of claim 1, wherein each wafer of the at least two wafers has three notches.

12. The wafer bonding apparatus of claim 1, wherein each wafer of the at least two wafers has four notches.

13. A wafer bonding method, comprising:
sensing at least two notches of each wafer of at least two wafers;
aligning the at least two wafers; and
bonding the at least two wafers.

14. The wafer bonding method of claim 13, further comprising measuring an alignment accuracy for wafer bonding after aligning the at least two wafers.

15. The wafer bonding method of claim 13, wherein the at least two notches of each wafer of the at least two wafers are provided in an equidistant arrangement.

16. The wafer bonding method of claim 13, wherein the at least two notches of each wafer of the at least two wafers are provided in a non-equidistant arrangement.

17. The wafer bonding method of claim 13, wherein at least one of the at least two notches of each wafer of the at least two wafers is provided an asymmetric structure.

18. The wafer bonding method of claim 13, wherein each wafer of the at least two wafers has exactly two notches.

19. The wafer bonding method of claim 13, wherein each wafer of the at least two wafers has three notches.

20. The wafer bonding method of claim 13, wherein each wafer of the at least two wafers has four notches.
